(19) United States
(12) Patent Application Publication
(10) Pub. No.: US 2024/0113684 A1
(43) Pub. Date: Apr. 4, 2024

(54) ACOUSTIC WAVE DEVICE

(71) Applicant: Murata Manufacturing Co., Ltd., Nagaokakyo-shi (JP)

(72) Inventor: Tetsuya KIMURA, Nagaokakyo-shi (JP)

(21) Appl. No.: 18/540,949

(22) Filed: Dec. 15, 2023

Related U.S. Application Data
(63) Continuation of application No. PCT/JP2022/023269, filed on Jun. 9, 2022.
(60) Provisional application No. 63/211,589, filed on Jun. 17, 2021.

(51) Int. Cl. H03H 9/17; H03H 9/02

(52) U.S. Cl. CPC H03H 9/173; H03H 9/02015; H03H 9/02157

(57) ABSTRACT

An acoustic wave device includes a support including a support substrate, a piezoelectric layer on the support substrate, a space overlapping at least a portion of the piezoelectric layer, and a functional electrode on the piezoelectric layer. The support includes a space at a position at least partially overlapping the functional electrode in plan view. The functional electrode includes a first metal layer and a second metal layer on at least a portion of the first metal layer. A linear expansion coefficient of the second metal layer is smaller than a linear expansion coefficient of the first metal layer.

### CROSS REFERENCE TO RELATED APPLICATIONS

This application claims the benefit of priority to Provisional Application No. 63/211,589 filed on Jun. 17, 2021 and is a Continuation application of PCT Application No. PCT/JP2022/023269 filed on Jun. 9, 2022. The entire contents of each application are hereby incorporated herein by reference.

### BACKGROUND OF THE INVENTION

### 1. Field of the Invention

The present disclosure relates to acoustic wave devices.

### 2. Description of the Related Art

Japanese Unexamined Patent Application Publication No. 2012-257019 describes an acoustic wave device.

The acoustic wave device described in Japanese Unexamined Patent Application Publication No. 2012-257019 generates heat during operation. At this time, since a linear expansion coefficient of a busbar electrode of a functional electrode is larger than a linear expansion coefficient of a piezoelectric layer, a portion where the piezoelectric layer is excessively bent occurs, and thus characteristics may be deteriorated.

### SUMMARY OF THE INVENTION

Example embodiments of the present invention provide acoustic wave devices which are each able to reduce or prevent excessive bending of a portion of the piezoelectric layer. An acoustic wave device according to an example embodiment of the present invention includes a support including a support substrate, a piezoelectric layer on the support, and a functional electrode on the piezoelectric layer, wherein the support includes a space at least partially overlapping the functional electrode in plan view, the functional electrode includes a first metal layer and a second metal layer on at least a portion of the first metal layer, and a linear expansion coefficient of the second metal layer is smaller than a linear expansion coefficient of the first metal layer.

An acoustic wave device according to an example embodiment of the present invention includes a support including a support substrate, a piezoelectric layer on the support, and functional electrodes on the piezoelectric layer and below the piezoelectric layer, wherein the support includes a space at least partially overlapping the functional electrodes in plan view, the functional electrodes each include a first metal layer and a second metal layer on at least a portion of the first metal layer, and a linear expansion coefficient of the second metal layer is smaller than a linear expansion coefficient of the first metal layer.

According to example embodiments of the present invention, it is possible to reduce or prevent excessive bending of a piezoelectric layer.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view illustrating an acoustic wave device according to a first example embodiment of the present invention.

FIG. 1B is a plan view illustrating an electrode structure of the first example embodiment of the present invention.

FIG. 2 is a sectional view of a portion taken along line II-II of FIG. 1A.

FIG. 3A is a schematic sectional view for explaining a Lamb wave propagating through a piezoelectric layer of a comparative example.

FIG. 3B is a schematic sectional view for explaining a bulk wave in a thickness-shear first-order mode propagating through a piezoelectric layer of the first example embodiment of the present invention.

FIG. 4 is a schematic sectional view for explaining an amplitude direction of the bulk wave in the thickness-shear first-order mode propagating through the piezoelectric layer of the first example embodiment of the present invention.

FIG. 5 is an explanatory diagram showing an example of resonance characteristics of the acoustic wave device of the first example embodiment of the present invention.

FIG. 6 is an explanatory diagram showing, in the acoustic wave device of the first example embodiment of the present invention, a relationship between d/2p and fractional bandwidth as a resonator, where p is a center-to-center distance between adjacent electrodes or an average distance of center-to-center distances, and d is an average thickness of the piezoelectric layer.

FIG. 7 is a plan view illustrating an example in which a pair of electrodes are provided in the acoustic wave device of the first example embodiment of the present invention.

FIG. 8 is a reference diagram showing an example of resonance characteristics of the acoustic wave device of the first example embodiment of the present invention.

FIG. 9 is an explanatory diagram showing a relationship between fractional bandwidth and phase rotation amount of impedance of spurious mode normalized by about 180 degrees as a magnitude of the spurious mode in the acoustic wave device of the first example embodiment of the present invention, when a large number of acoustic wave resonators are provided.

FIG. 10 is an explanatory diagram showing a relationship among d/2p, metallization ratio MR, and fractional bandwidth.

FIG. 11 is an explanatory diagram showing a map of fractional bandwidth with respect to Euler angles (0°, θ, ψ) of LiNbO₃ when d/p is made to approach 0 as much as possible.

FIG. 12 is a partially cutaway perspective view for explaining an acoustic wave device according to an example embodiment of the present invention.

FIG. 13 is a sectional view for explaining an acoustic wave device according to an example embodiment of the present invention.

FIG. 14 is a perspective view illustrating an example of the acoustic wave device according to the first example embodiment of the present invention.

FIG. 15 is a sectional view taken along line XV-XV of FIG. 14.

FIG. 16 is a diagram showing a distribution of displacement in a Z direction of a piezoelectric layer of an acoustic wave device according to Test Example 1.

FIG. 17 is a diagram showing a distribution of displacement in the Z direction of a piezoelectric layer of an acoustic wave device according to Test Example 2.

FIG. 18 is a diagram showing a distribution of displacement in the Z direction of a piezoelectric layer of an acoustic wave device according to Test Example 3.

FIG. 19 is a diagram showing the displacement in the Z direction of the piezoelectric layer along line A-A′ in FIG. 16 to FIG. 18.

FIG. 20 is a sectional view illustrating a first modification of the acoustic wave device according to the first example embodiment of the present invention.

FIG. 21 is a sectional view illustrating a second modification of the acoustic wave device according to the first example embodiment of the present invention.

FIG. 22 is a sectional view illustrating a third modification of the acoustic wave device according to the first example embodiment of the present invention.

FIG. 23 is a sectional view illustrating a fourth modification of the acoustic wave device according to the first example embodiment of the present invention.

### DETAILED DESCRIPTION OF THE EXAMPLE EMBODIMENTS

Hereinafter, example embodiments of the present invention will be described in detail with reference to the drawings. The present invention is not limited by the example embodiments. Each example embodiment described in the present disclosure is merely an example, and in modifications and second and subsequent example embodiments in which partial replacement or combination of configurations is possible between different example embodiments, description of matters common to the first example embodiment will be omitted, and only different points will be described. In particular, the same or similar advantageous effects by the same or similar configurations will not be described in each example embodiment.

### First Example Embodiment

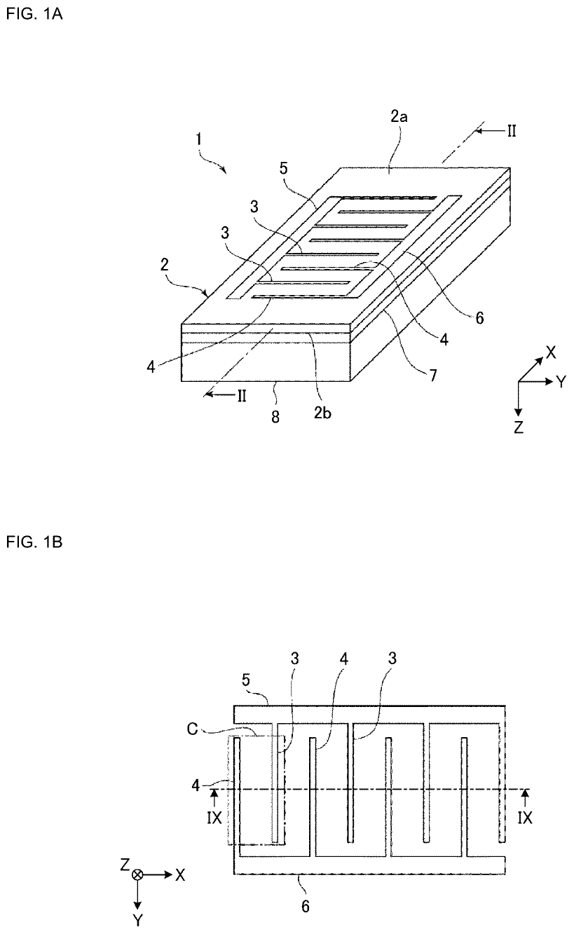

FIG. 1A is a perspective view illustrating an acoustic wave device according to a first example embodiment of the present invention. FIG. 1B is a plan view illustrating an electrode structure of the first example embodiment.

An acoustic wave device 1 of the first example embodiment includes a piezoelectric layer 2 made of, for example, LiNbO₃. The piezoelectric layer 2 may be made of, for example, LiTaO₃. A cut angle of LiNbO₃ or LiTaO₃ is, for example, Z cut in the first example embodiment. The cut angle of LiNbO₃ or LiTaO₃ may be, for example, rotated Y cut or X cut. Preferably, for example, propagation directions of Y propagation and X propagation are about ±30°.

A thickness of the piezoelectric layer 2 is not particularly limited but is preferably, for example, equal to or greater than about 50 nm and equal to or less than about 1000 nm in order to effectively excite a thickness-shear first-order mode.

The piezoelectric layer 2 includes a first main surface 2a and a second main surface 2b opposed to each other in a Z direction. An electrode finger 3 and an electrode finger 4 are provided on the first main surface 2a.

Here, the electrode finger 3 is an example of a “first electrode finger”, and the electrode finger 4 is an example of a “second electrode finger”. In FIGS. 1A and 1B, a plurality of electrode fingers 3 is a plurality of “first fingers” connected to a first busbar electrode 5. A plurality of electrode fingers 4 is a plurality of “second electrode fingers” connected to a second busbar electrode 6. The plurality of electrode fingers 3 and the plurality of electrode fingers 4 are interdigitated with each other. Thus, an interdigital transducer (IDT) electrode including the electrode finger 3, the electrode finger 4, the first busbar electrode 5, and the second busbar electrodes 6 is provided.

The electrode finger 3 and the electrode finger 4 each have a rectangular or substantially rectangular shape and a length direction. In a direction orthogonal or substantially orthogonal to the length direction, the electrode finger 3 and the electrode finger 4 adjacent to the electrode finger 3 face each other. Either of the length direction of the electrode fingers 3 and 4 and the direction orthogonal or substantially orthogonal to the length direction of the electrode fingers 3 and 4 is a direction intersecting a thickness direction of the piezoelectric layer 2. Thus, it can be said that the electrode finger 3 and the electrode finger 4 adjacent to the electrode finger 3 face each other in the direction intersecting the thickness direction of the piezoelectric layer 2. In the following description, the thickness direction of the piezoelectric layer 2 may be referred to as the Z direction, the length direction of the electrodes finger 3 and 4 may be referred to as a Y direction (or a first direction), and a direction orthogonal or substantially orthogonal to the electrode fingers 3 and 4 may be referred to as an X direction (or a second direction).

Further, the length direction of the electrode fingers 3 and 4 may be replaced with a direction orthogonal or substantially orthogonal to the length direction of the electrode fingers 3 and 4 illustrated in FIGS. 1A and 1B. That is, in FIGS. 1A and 1B, the electrode fingers 3 and 4 may be extended in a direction in which the first busbar electrode 5 and the second busbar electrode 6 extend. In this case, the first busbar electrode 5 and the second busbar electrode 6 extend in a direction in which the electrode fingers 3 and 4 extend in FIGS. 1A and 1B. Then, a plurality of structures in each of which the electrode finger 3 connected to one potential and the electrode finger 4 connected to another potential are adjacent to each other and define a pair is provided in the direction orthogonal or substantially orthogonal to the length direction of the electrode fingers 3 and 4 described above.

Here, the case where the electrode finger 3 and the electrode finger 4 are adjacent to each other indicates a case where the electrode finger 3 and the electrode finger 4 are disposed with a gap interposed therebetween, not a case where the electrode finger 3 and the electrode finger 4 are disposed so as to be in direct contact with each other. Further, when the electrode finger 3 and the electrode finger 4 are adjacent to each other, no electrode connected to a hot electrode or a ground electrode, including the other electrode fingers 3 and 4 is disposed between the electrode finger 3 and the electrode finger 4. The number of pairs is not necessarily an integer, and may be 1.5, 2.5, or the like.

A center-to-center distance, that is, a pitch, between the electrode finger 3 and the electrode finger 4 is preferably, for example, in a range from equal to or greater than about 1 μm to equal to or less than about 10 μm. Further, the center-to-center distance between the electrode finger 3 and the electrode finger 4 is a distance between a center of a width dimension of the electrode finger 3 in the direction orthogonal or substantially orthogonal to the length direction of the electrode finger 3 and a center of a width dimension of the electrode finger 4 in the direction orthogonal or substantially orthogonal to the length direction of the electrode finger 4.

Further, when at least one of the electrode fingers 3 and 4 is plural (in a case where there are 1.5 or more electrode pairs, when the electrode fingers 3 and 4 are defined as one electrode pair), the center-to-center distance between the electrode fingers 3 and 4 is an average of the center-to-center distances between the respective pairs of adjacent electrode fingers 3 and 4 among the 1.5 or more pairs of the electrode fingers 3 and 4.

Further, widths of the electrode fingers 3 and 4, that is, dimensions of the electrode fingers 3 and 4 in an opposing direction, are preferably, for example, in a range from equal to or greater than about 150 nm to equal to or less than about 1000 nm. The center-to-center distance between the electrode finger 3 and the electrode finger 4 is the distance between the center of the dimension (width dimension) of the electrode finger 3 in the direction orthogonal or substantially orthogonal to the length direction of the electrode finger 3 and the center of the dimension (width dimension) of the electrode finger 4 in the direction orthogonal or substantially orthogonal to the length direction of the electrode finger 4.

Further, in the first example embodiment, since the Z-cut piezoelectric layer is used, the direction orthogonal or substantially orthogonal to the length direction of the electrode fingers 3 and 4 is a direction orthogonal or substantially orthogonal to a polarization direction of the piezoelectric layer 2. This is not the case when a piezoelectric material having a different cut angle is used as the piezoelectric layer 2. Here, the term “orthogonal” is not limited to a case of being strictly orthogonal, and may be substantially orthogonal (an angle between the direction orthogonal to the length direction of the electrode fingers 3 and 4, and the polarization direction is, for example, about 90°±10°).

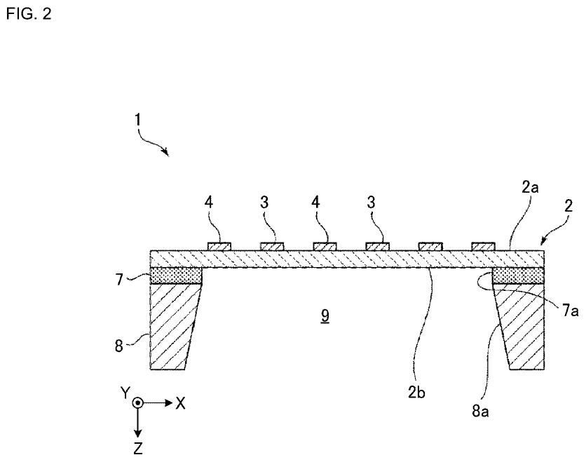

A support substrate 8 is laminated close to the second main surface 2b of the piezoelectric layer 2 with a dielectric layer 7 interposed therebetween. The dielectric layer 7 and the support substrate 8 each have a frame shape, and include cavities 7a and 8a as illustrated in FIG. 2. Thus, a space (air gap) 9 is provided.

The space 9 is provided in order not to hinder a vibration of an excitation region C of the piezoelectric layer 2. Thus, the above-described support substrate 8 is laminated on the second main surface 2b with the dielectric layer 7 interposed therebetween at a position not overlapping a portion where at least one pair of the electrode fingers 3 and 4 are provided. The dielectric layer 7 need not be provided. Thus, the support substrate 8 can be laminated directly or indirectly on the second main surface 2b of the piezoelectric layer 2.

The dielectric layer 7 is made of, for example, silicon oxide. However, the dielectric layer 7 may be made of an appropriate insulating material such as, for example, silicon nitride or alumina, in addition to silicon oxide.

The support substrate 8 is made of, for example, Si. A plane orientation of Si on a surface close to the piezoelectric layer 2 may be (100), (110), or may be (111). Preferably, Si with a high resistance of, for example, equal to or greater than about 4 kΩ is desirable. However, the support substrate 8 may also be made using an appropriate insulating material or semiconductor material. As the material of the support substrate 8, for example, piezoelectric materials such as aluminum oxide, lithium tantalate, lithium niobate and quartz, various ceramics such as alumina, magnesia, sapphire, silicon nitride, aluminum nitride, silicon carbide, zirconia, cordierite, mullite, steatite and forsterite, dielectrics such as diamond and glass, and semiconductors such as gallium nitride can be used.

The plurality of electrode fingers 3 and 4, the first busbar electrode 5 and the second busbar electrode 6 described above are made of appropriate metal or alloy such as, for example, Al or an AlCu alloy. In the first example embodiment, the electrode fingers 3 and 4, the first busbar electrode 5 and the second busbar electrode 6 include, for example, an Al film laminated on a Ti film. An adhesion layer other than the Ti film may be used.

During driving, an AC voltage is applied between the plurality of electrode fingers 3 and the plurality of electrode fingers 4. More specifically, an AC voltage is applied between the first busbar electrode 5 and the second busbar electrode 6. This makes it possible to obtain resonance characteristics in which a bulk wave in a thickness-shear first-order mode excited in the piezoelectric layer 2 is used.

In addition, in the acoustic wave device 1, d/p is set to be, for example, equal to or less than about 0.5, where d is the thickness of the piezoelectric layer 2, and p is the center-to-center distance between any adjacent electrode fingers 3 and 4 from the plurality of pairs of electrode fingers 3 and 4. Thus, the bulk wave in the thickness-shear first-order mode described above is effectively excited, and good resonance characteristics can be obtained. More preferably, for example, d/p is equal to or less than about 0.24, and in this case, even better resonance characteristics can be obtained.

When at least one of the electrode fingers 3 and 4 is plural as in the first example embodiment, that is, in the case where there are 1.5 or more pairs of the electrode fingers 3 and 4 when the electrode fingers 3 and 4 are defined as one electrode pair, the center-to-center distance p between the adjacent electrode fingers 3 and 4 is the average distance of the center-to-center distances between the respective pairs of adjacent electrode fingers 3 and 4.

Since the acoustic wave device 1 of the first example embodiment has the above-described configuration, even when the number of pairs of the electrode fingers 3 and 4 is reduced in order to achieve miniaturization, a decrease in a Q value is unlikely to occur, because this is a resonator that does not require reflectors on both sides, and has a small propagation loss. Further, the reason why the above reflector is not required is that the bulk wave in the thickness-shear first-order mode is used.

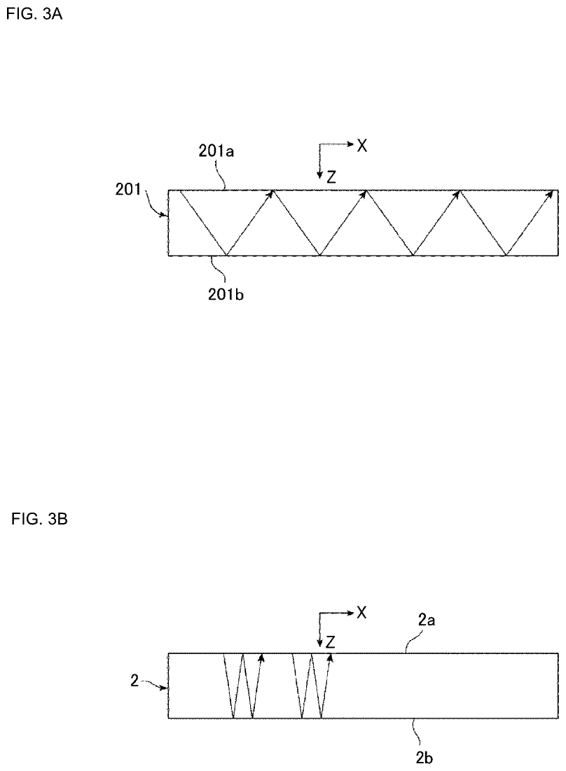

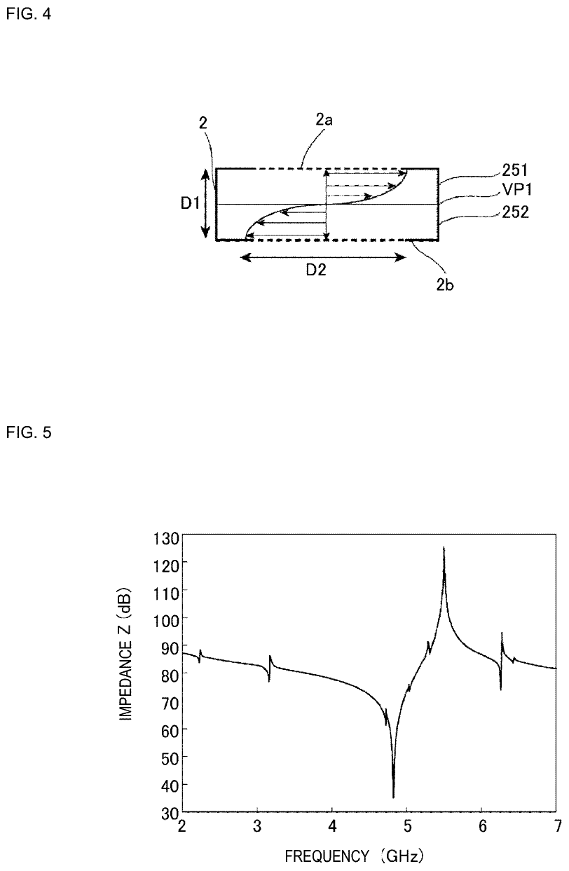

FIG. 3A is a schematic sectional view for explaining a Lamb wave propagating through a piezoelectric layer of a comparative example. FIG. 3B is a schematic sectional view for explaining the bulk wave in the thickness-shear first-order mode propagating through the piezoelectric layer of the first example embodiment. FIG. 4 is a schematic sectional view for explaining an amplitude direction of the bulk wave in the thickness-shear first-order mode propagating through the piezoelectric layer of the first example embodiment.

FIG. 3A illustrates an acoustic wave device as described in Japanese Unexamined Patent Application Publication No. 2012-257019, and the Lamb wave propagates through the piezoelectric layer. As illustrated in the FIG. 3A, the wave propagates in a piezoelectric layer 201 as indicated by arrows. Here, the piezoelectric layer 201 includes a first main surface 201a and a second main surface 201b, and a thickness direction in which the first main surface 201a and the second main surface 201b are connected is the Z direction. The X direction is a direction in which the electrode fingers 3 and 4 of the IDT electrode are aligned. As illustrated in FIG. 3A, in the case of the Lamb wave, the wave propagates in the X direction as illustrated. Although the piezoelectric layer 201 vibrates as a whole because of a plate wave, the wave propagates in the X direction, and thus reflectors are disposed on both sides to obtain resonance characteristics. Thus, a propagation loss of the wave occurs, and when miniaturization is achieved, that is, when the number of pairs of the electrode fingers 3 and 4 is reduced, a Q value is reduced.

On the other hand, as illustrated in FIG. 3B, in the acoustic wave device of the first example embodiment, vibration displacement is in a thickness shear direction, and thus a wave propagates substantially in a direction in which the first main surface 2a and the second main surface 2b of the piezoelectric layer 2 are connected, that is, in the Z direction, and resonates. That is, an X direction component of the wave is significantly smaller than a Z direction component. Then, since resonance characteristics are obtained by the propagation of the wave in the Z direction, no reflector is required. Thus, no propagation loss occurs during propagation to a reflector. Thus, even when the number of electrode pairs each including the electrode fingers 3 and 4 is reduced to achieve miniaturization, the Q value is unlikely to be reduced.

As illustrated in FIG. 4, an amplitude direction of the bulk wave in the thickness-shear first-order mode reverses between a first region 251 included in the excitation region C (see FIG. 1B) of the piezoelectric layer 2 and a second region 252 included in the excitation region C. FIG. 4 schematically illustrates a bulk wave when a voltage is applied between the electrode finger 3 and the electrode finger 4 such that the electrode finger 4 has a higher potential than that of the electrode finger 3. The first region 251 is a region of the excitation region C between the first main surface 2a, and a virtual plane VP1 that is orthogonal or substantially orthogonal to the thickness direction of the piezoelectric layer 2 and divides the piezoelectric layer 2 into two parts. The second region 252 is a region of the excitation region C between the virtual plane VP1 and the second main surface 2b.

In the acoustic wave device 1, at least one pair of electrodes including the electrode finger 3 and the electrode finger 4 are provided, but since a wave is not propagated in the X direction, the number of electrode pairs including the electrode fingers 3 and 4 is not necessarily plural. That is, it is sufficient that at least one pair of electrodes is provided.

For example, the electrode finger 3 is an electrode connected to a hot potential, and the electrode finger 4 is an electrode connected to a ground potential. However, the electrode finger 3 may be connected to the ground potential, and the electrode finger 4 may be connected to the hot potential. In the first example embodiment, as described above, the at least one pair of electrodes includes the electrode connected to the hot potential or the electrode connected to the ground potential, and no floating electrode is provided.

FIG. 5 is an explanatory diagram showing an example of resonance characteristics of the acoustic wave device of the first example embodiment. Design parameters of the acoustic wave device 1 having the resonance characteristics shown in FIG. 5 are as follows.

Piezoelectric layer 2: LiNbO₃ having Euler angles (0°, 0°, 90°)

Thickness of piezoelectric layer 2: about 400 nm

Length of excitation region C (see FIG. 1B): about 40 μm

The number of pairs of electrodes including electrode fingers 3 and 4: 21

Center-to-center distance (pitch) between electrode finger 3 and electrode finger 4: about 3 μm

Width of each of electrode fingers 3 and 4: about 500 nm

d/p: about 0.133

Dielectric layer 7: a silicon oxide film having a thickness of about 1 μm

Support substrate 8: Si

The excitation region C (see FIG. 1B) is a region where the electrode finger 3 and the electrode finger 4 overlap each other when viewed in the X direction orthogonal or substantially orthogonal to the length direction of the electrode 3 and the electrode finger 4. A length of the excitation region C is a dimension of the excitation region C along the length direction of the electrode fingers 3 and 4. Here, the excitation region C is an example of an “intersection region”.

In the first example embodiment, an inter-electrode distance of the electrode pairs including the electrode fingers 3 and 4 is equally or substantially equally set for all of the plurality of pairs. That is, the electrode fingers 3 and the electrode fingers 4 are disposed at an equal or substantially equal pitch.

As is clear from FIG. 5, although no reflector is included, good resonance characteristics with a fractional bandwidth of about 12.5% are obtained.

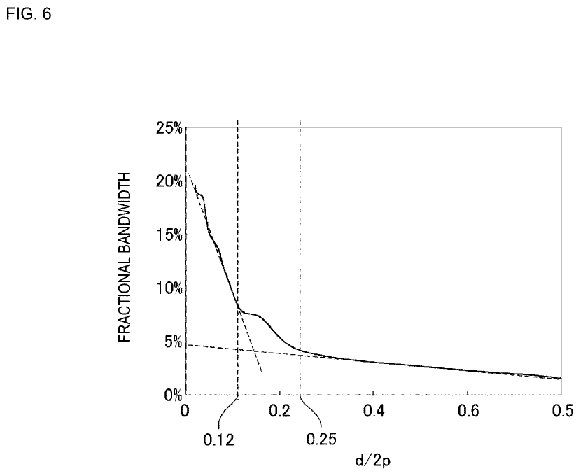

Incidentally, for example, d/p is equal to or less than about 0.5, and more preferably equal to or less than about 0.24, in the first example embodiment, where d is the thickness of the piezoelectric layer 2, and p is the center-to-center distance between the electrode finger 3 and the electrode finger 4. This will be described with reference to FIG. 6.

A plurality of acoustic wave devices were obtained in the same or substantially the same manner as the acoustic wave device having the resonance characteristics shown in FIG. 5, except that d/2p was changed. FIG. 6 is an explanatory diagram showing, in the acoustic wave device of the first example embodiment, a relationship between d/2p and fractional bandwidth as a resonator, where p is the center-to-center distance between adjacent electrodes or an average distance of center-to-center distances, and d is an average thickness of the piezoelectric layer 2.

As shown in FIG. 6, when d/2p exceeds about 0.25, that is, when d/p>about 0.5, the fractional bandwidth is less than about 5% even when d/p is adjusted. On the other hand, when d/2p≤about 0.25, that is, d/p≤about 0.5, the fractional bandwidth can be made to be equal to or greater than about 5% by changing d/p within the range, that is, a resonator having a high coupling coefficient can be provided. Further, when d/2p is equal to or less than about 0.12, that is, when d/p is equal to or less than about 0.24, the fractional bandwidth can be increased to equal to or greater than about 7%. In addition, when d/p is adjusted within this range, a resonator having a wider fractional bandwidth can be obtained, and a resonator having a higher coupling coefficient can be achieved. Thus, it is understood that a resonator having a high coupling coefficient in which the bulk wave of the thickness-shear first-order mode is utilized can be provided by setting d/p to be, for example, equal to or less than about 0.5.

The at least one pair of electrodes may be one pair, and in a case of one pair of electrodes, the above-described p is a center-to-center distance between the adjacent electrode fingers 3 and 4. In addition, in a case of 1.5 or more pairs of electrodes, it is sufficient that an average distance of the center-to-center distances between the respective pairs of adjacent electrode fingers 3 and 4 is used as p.

In addition, when the piezoelectric layer 2 has a variation in thickness, it is sufficient to use an average value of the thickness for the thickness d of the piezoelectric layer 2 as well.

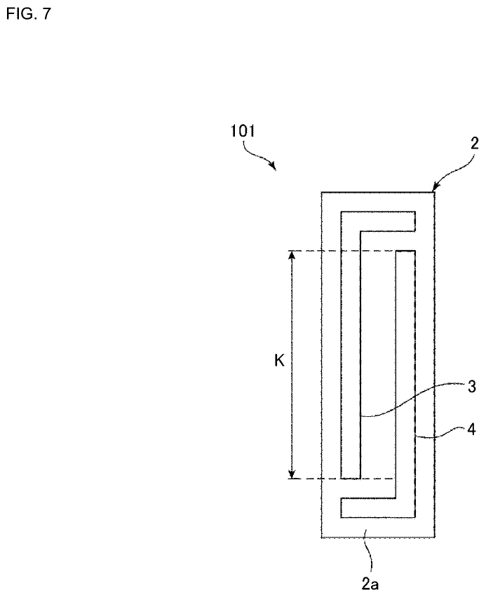

FIG. 7 is a plan view illustrating an example in which a pair of electrodes are provided in the acoustic wave device of the first example embodiment. In an acoustic wave device 101, a pair of electrodes including the electrode finger 3 and the electrode finger 4 are provided on the first main surface 2a of the piezoelectric layer 2. In FIG. 7, K is an intersecting width. As described above, in the acoustic wave devices according to example preferred embodiments of the present invention, the number of pairs of electrodes may be one. In this case as well, as long as d/p described above is equal to or less than about 0.5, the bulk wave in the thickness-shear first-order mode can be effectively excited.

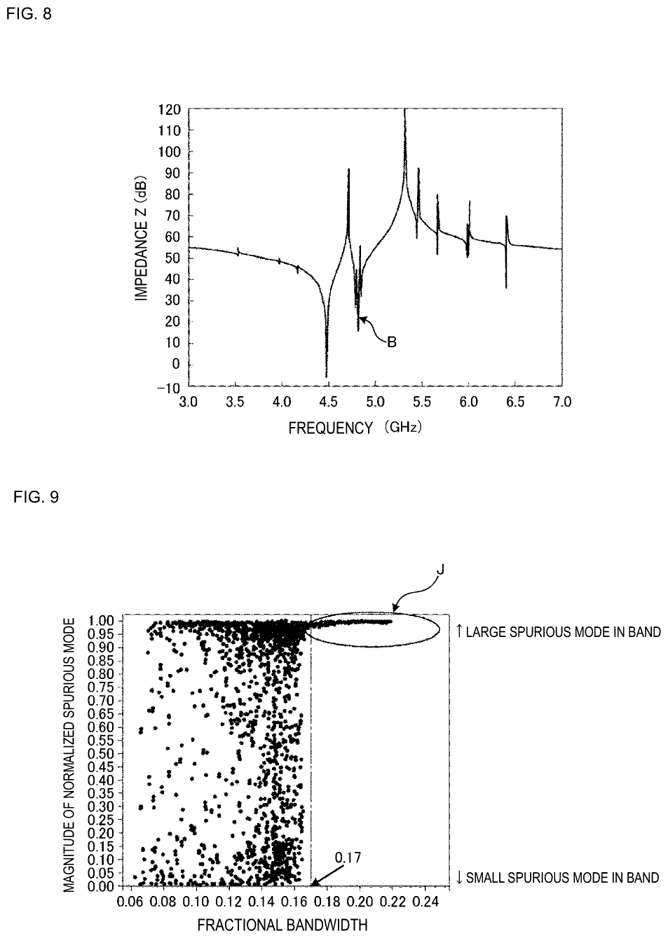

In the acoustic wave device 1, preferably, the metallization ratio MR of the above-described adjacent electrode fingers 3 and 4 to the excitation region C, which is the region where any pair of adjacent electrode fingers 3 and 4 overlap each other when viewed in the direction in which the adjacent electrode fingers 3 and 4 face each other, in the plurality of electrode fingers 3 and 4, preferably satisfies, for example, MR≤about 1.75(d/p)+0.075. In this case, a spurious mode can be effectively reduced. This will be described with reference to FIG. 8 and FIG. 9.

FIG. 8 is a reference diagram showing an example of the resonance characteristics of the acoustic wave device of the first example embodiment. A spurious mode indicated by an arrow B appears between a resonant frequency and an anti-resonant frequency. d/p was set to about 0.08 and the Euler angles of LiNbO₃ were set to (0°, 0°, 90°). In addition, the above-described metallization ratio MR was set to about 0.35.

The metallization ratio MR will be explained with reference to FIG. 1B. In the electrode structure in FIG. 1B, when focusing on a pair of the electrode fingers 3 and 4, only this pair of the electrode fingers 3 and 4 is provided. In this case, a portion surrounded by a one dot chain line is the excitation region C. This excitation region C is a region of the electrode finger 3 overlapping the electrode finger 4, a region of the electrode finger 4 overlapping the electrode finger 3, and a region in a region between the electrode finger 3 and the electrode finger 4 where the electrode finger 3 and the electrode finger 4 overlap each other, when the electrode finger 3 and the electrode finger 4 are viewed in the direction orthogonal or substantially orthogonal to the length direction of the electrode fingers 3 and 4, that is, in the opposing direction. Then, areas of the electrode fingers 3 and 4 in the excitation region C with respect to an area of the excitation region C result in the metallization ratio MR. That is, the metallization ratio MR is a ratio of an area of a metallization portion to the area of the excitation region C.

When a plurality of pairs of the electrode fingers 3 and 4 are provided, it is sufficient that a ratio of metallization portions included in all of the excitation regions C to a total of areas of the excitation regions C is used as MR.

FIG. 9 is an explanatory diagram showing a relationship between fractional bandwidth and phase rotation amount of impedance of spurious mode normalized by about 180 degrees as a magnitude of the spurious mode in the acoustic wave device of the first example embodiment, when a large number of acoustic wave resonators are provided. The fractional bandwidth was adjusted by variously changing a film thickness of the piezoelectric layer 2 and the dimensions of the electrode fingers 3 and 4. Further, FIG. 9 shows a result when the piezoelectric layer 2 made of Z-cut LiNbO₃ was used, but the same or similar tendency is obtained also when the piezoelectric layer 2 having another cut angle is used.

In a region surrounded by an ellipse J in FIG. 9, the spurious mode is as large as about 1.0. As is clear from FIG. 9, when the fractional bandwidth exceeds about 0.17, that is, when the fractional bandwidth exceeds about 17%, a large spurious mode having a spurious level of equal to or greater than about 1 appears in a pass band even when parameters for forming the fractional bandwidth are changed. That is, as in the resonance characteristics shown in FIG. 8, the large spurious mode indicated by the arrow B appears in the band. Thus, the fractional bandwidth is preferably, for example, equal to or less than about 17%. In this case, the spurious mode can be reduced by adjusting the film thickness of the piezoelectric layer 2, the dimensions of the electrode fingers 3 and 4, and the like.

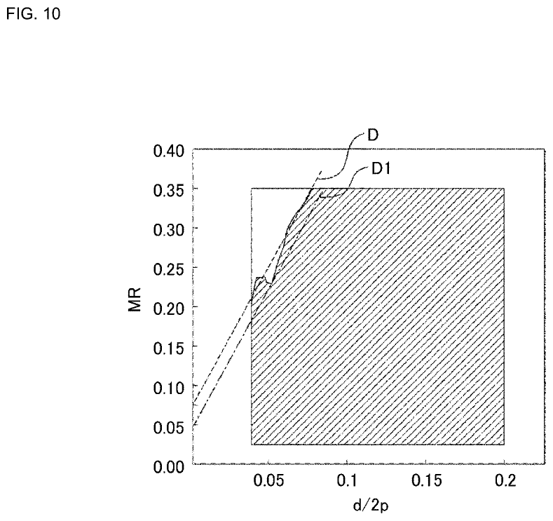

FIG. 10 is an explanatory diagram showing a relationship among d/2p, the metallization ratio MR and the fractional bandwidth. As for the acoustic wave device 1 of the first example embodiment, various acoustic wave devices 1 having different d/2p and MR were provided, and the fractional bandwidth was measured. A hatched portion on a right side of a broken line D in FIG. 10 is a region where the fractional bandwidth is equal to or less than about 17%. A boundary between the hatched region and an unhatched region is represented by MR=about 3.5(d/2p)+0.075. That is, MR=about 1.75(d/p)+0.075. Thus, preferably, for example, MR≤about 1.75 (d/p)+0.075. In this case, the fractional bandwidth is easily set to be equal to or less than about 17%. A region on the right side of MR=about 3.5(d/2p)+0.05 indicated by a dashed line D1 in FIG. 10 is more preferable. That is, for example, as long as MR≤about 1.75(d/p)+0.05, the fractional bandwidth can be reliably set to be equal to or less than about 17%.

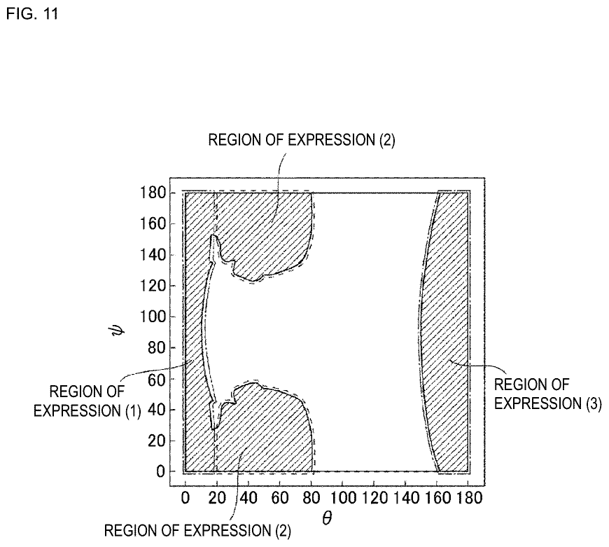

FIG. 11 is an explanatory diagram showing a map of the fractional bandwidth with respect to Euler angles (0°, θ, ψ) of LiNbO₃ when d/p is made to approach 0 as much as possible. A hatched portion in FIG. 11 is a region where a fractional bandwidth of at least equal to or greater than about 5% is obtained. A range of the region is approximated to a range represented by Expressions (1), (2), and (3) below.

(0°±10°, 0° to 20°, any ψ) Expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Expression (2)

(0°±10°, [180°−30° (1−(ψ−90)²/8100)^{1/2}] to 180°, any ψ) Expression (3)

Thus, the fractional bandwidth can be sufficiently widened in the case of the Euler angles in Expression (1), (2), or (3) described above, which is preferable.

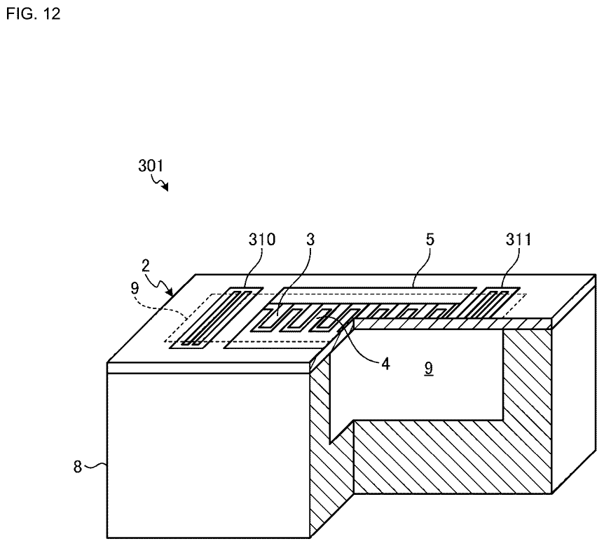

FIG. 12 is a partially cutaway perspective view for explaining an acoustic wave device according to an example embodiment of the present invention. In FIG. 12, an outer peripheral edge of the space 9 is indicated by a broken line. The acoustic wave device according to present example embodiment may be one in which a plate wave is utilized. In this case, as illustrated in FIG. 12, an acoustic wave device 301 includes reflectors 310 and 311. The reflectors 310 and 311 are provided on both sides in an acoustic wave propagation direction of the electrode fingers 3 and 4 of the piezoelectric layer 2, respectively. In the acoustic wave device 301, by applying an alternating electric field to the electrode fingers 3 and 4 on the space 9, a Lamb wave as a plate wave is excited. At this time, since the reflectors 310 and 311 are provided on both the sides, respectively, resonance characteristics by the Lamb wave as the plate wave can be obtained.

As described above, the bulk wave in the thickness-shear first-order mode is used in the acoustic wave devices 1 and 101. In addition, in the acoustic wave devices 1 and 101, the first electrode finger 3 and the second electrode finger 4 are the electrodes adjacent to each other, and d/p is, for example, equal to or less than about 0.5, where d is the thickness of the piezoelectric layer 2, and p is the center-to-center distance between the first electrode finger 3 and the second electrode finger 4. Thus, even when the acoustic wave device is miniaturized, a Q value can be increased.

In the acoustic wave devices 1 and 101, the piezoelectric layer 2 is made of, for example, lithium niobate or lithium tantalate. It is preferable that the first electrode finger 3 and the second electrode finger 4 facing each other in the direction intersecting the thickness direction of the piezoelectric layer 2 be present on the first main surface 2a or the second main surface 2b of the piezoelectric layer 2, and an upside of the first electrode finger 3 and the second electrode finger 4 is covered with a protective film.

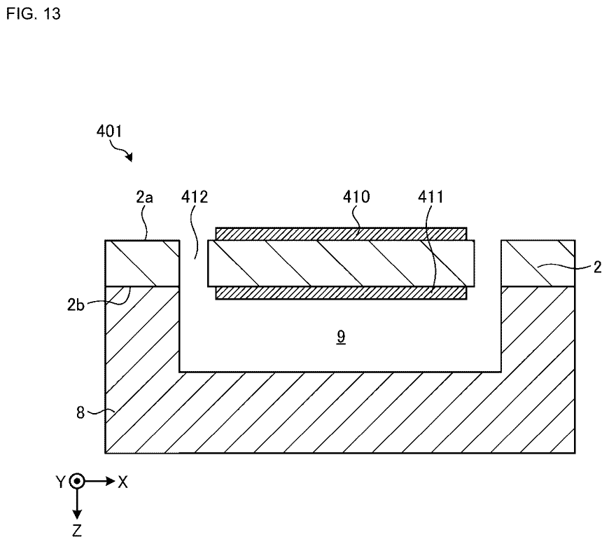

FIG. 13 is a sectional view for explaining an acoustic wave device according to an example embodiment of the present invention. The acoustic wave device of the present example embodiment may be a device in which a bulk wave is utilized as illustrated in FIG. 13, that is, a bulk acoustic wave (BAW) element. In this case, an acoustic wave device 401 includes functional electrodes 410 and 411. The functional electrode 410 is an electrode provided on the first main surface 2a of the piezoelectric layer 2. The functional electrode 411 is an electrode provided on the second main surface 2b of the piezoelectric layer 2. In FIG. 13, the functional electrode 410 is an example of an “upper electrode”, and the functional electrode 411 is an example of a “lower electrode”. In the example of FIG. 13, the support substrate 8 includes the space 9 close to the piezoelectric layer 2, and the functional electrode 411 is provided in the space 9.

In the example of FIG. 13, a through-hole 412 is provided in the piezoelectric layer 2. The through-hole 412 penetrates the piezoelectric layer 2 in the Z direction. The through-hole 412 communicates with the space 9. When the through-hole 412 in the piezoelectric layer 2 is provided, by pouring an etching solution from the through-hole 412 after the piezoelectric layer 2 is bonded to the support substrate 8, a sacrificial layer provided in the space 9 in advance before the bonding can be etched.

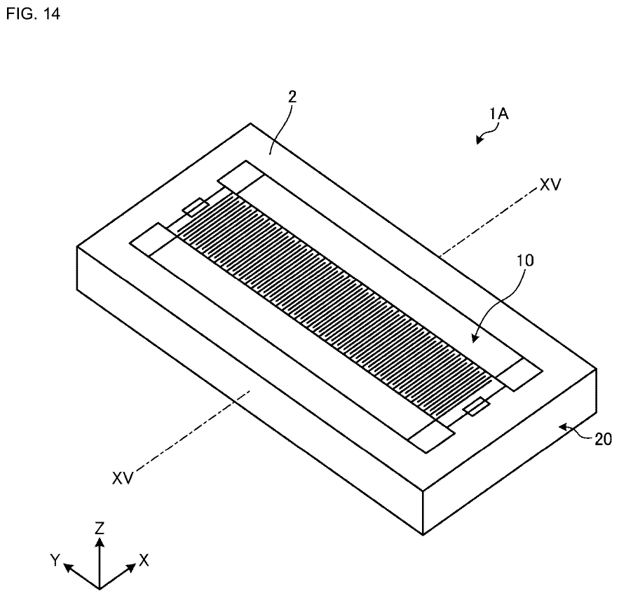

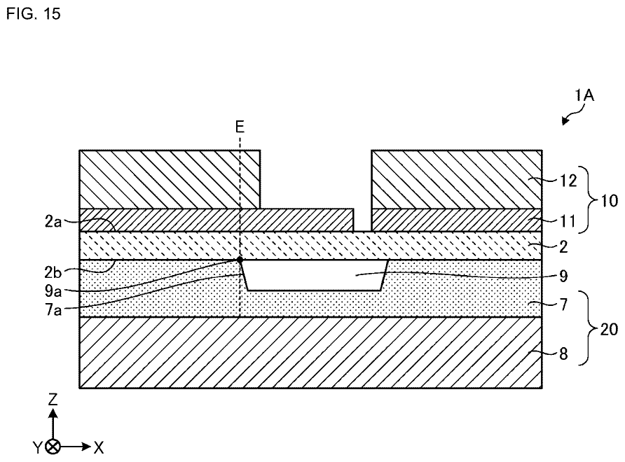

FIG. 14 is a perspective view illustrating an example of the acoustic wave device according to the first example embodiment. FIG. 15 is a sectional view taken along line XV-XV of FIG. 14. As illustrated in FIG. 14 and FIG. 15, an acoustic wave device 1A according to the first example embodiment includes a support 20, the piezoelectric layer 2 and a functional electrode 10. Here, in the following description, of directions parallel or substantially parallel to the Z direction, one direction may be referred to as “above”, and the other direction may be referred to as “below”. In the acoustic wave device 1A, the piezoelectric layer 2 is provided on the support 20.

The support 20 has a thickness in the Z direction and includes the support substrate 8. In the first example embodiment, the support 20 includes the support substrate 8 and the dielectric layer 7. The support 20 includes the space 9 at a position at least partially overlapping the functional electrode 10 in plan view in the Z direction. In the example of FIG. 15, the space 9 is provided on a surface of the dielectric layer 7 close to the piezoelectric layer 2. The space 9 may penetrate the dielectric layer 7, or may penetrate both of the dielectric layer 7 and the support substrate 8. In addition, the space 9 may penetrate the support 20.

The functional electrode 10 is provided on the piezoelectric layer 2. In the example of FIG. 14 and FIG. 15, the functional electrode 10 is provided on the first main surface 2a of the piezoelectric layer 2. The functional electrode 10 includes a wiring electrode and an IDT electrode. The wiring electrode connects a resonator including the IDT electrode to another element. The functional electrode 10 includes a first metal layer 11 and a second metal layer 12. The functional electrodes 10 may be provided on the first main surface 2a and the second main surface 2b of the piezoelectric layer 2.

The first metal layer 11 is provided on the piezoelectric layer 2. In the example of FIG. 14, the first metal layer 11 defines the electrode fingers 3 and 4 and the busbar electrodes 5 and 6. The first metal layer 11 includes, for example, aluminum (Al). Thus, good frequency characteristics can be obtained. The first metal layer 11 is not limited to being made of a single metal, and may be made of alloy, for example. Further, the first metal layer 11 is not limited to being provided so as to be in contact with the first main surface 2a of the piezoelectric layer 2. The first metal layer 11 may be laminated on the piezoelectric layer 2 with a layer interposed therebetween that is made of a material different from the material of the first metal layer 11, such as, for example, titanium (Ti) or chromium (Cr).

The second metal layer 12 is laminated on at least a portion of the first metal layer 11. In the first example embodiment, the second metal layer 12 is laminated on the first metal layer 11 and is thicker than the first metal layer 11. In the example of FIG. 15, the second metal layer 12 defines the wiring electrode. The second metal layer 12 is made of a metal having a low electrical resistance, and a linear expansion coefficient smaller than that of the first metal layer 11. The second metal layer 12 includes, for example, gold (Au) or copper (Cu). Thus, the first metal layer 11 is supported by the second metal layer 12 having a linear expansion coefficient smaller than that of the first metal layer 11, and thus occurrence of a portion where the piezoelectric layer 2 is excessively bent can be suppressed. The second metal layer 12 is not limited to being made of a single metal, and may be made of alloy, for example.

A difference in linear expansion coefficient between the piezoelectric layer 2 and the second metal layer 12 is smaller than a difference in linear expansion coefficient between the piezoelectric layer 2 and the first metal layer 11. Here, when the piezoelectric layer 2 is made of a material having an anisotropic linear expansion coefficient, such as, for example, lithium niobate (LiNbO₃), it is sufficient that a difference between a linear expansion coefficient of the piezoelectric layer 2 in the direction orthogonal or substantially orthogonal to the thickness direction and a linear expansion coefficient of the second metal layer 12 is smaller than a difference between a linear expansion coefficient of the piezoelectric layer 2 in the direction orthogonal or substantially orthogonal to the thickness direction and a linear expansion coefficient of the first metal layer 11. Thus, the first metal layer 11 is supported by the second metal layer 12 having a linear expansion coefficient close to that of the piezoelectric layer 2, and thus occurrence of a portion where the piezoelectric layer 2 is excessively bent can be reduced or prevented.

Table 1 is a list of coefficients of linear expansion of materials included in the acoustic wave device according to the first example embodiment. From Table 1, for example, when the first metal layer 11 is made of Al and the second metal layer 12 is made of Au or Cu, the linear expansion coefficient of the second metal layer 12 can be made smaller than the linear expansion coefficient of the first metal layer 11. In this case, from Table 1, when the piezoelectric layer 2 is made of, for example, ZY cut LiNbO₃, that is, when Euler angles are (0°, 37.5°, 0°), a difference between a linear expansion coefficient of the piezoelectric layer 2 and a linear expansion coefficient of the second metal layer 12 in an XY plane direction can be made smaller than a difference between the linear expansion coefficient of the piezoelectric layer 2 and a linear expansion coefficient of the first metal layer 11 in the XY plane direction.

TABLE 1

| Material | Linear expansion coefficient [10⁻⁵/K] |
|---|---|
| LiNbO₃ (ZY cut) | XY plane direction: 1.54 |
| | Z direction: 0.75 |
| Al | 2.31 |
| Cu | 1.65 |
| Au | 1.42 |
| SiO₂ | 0.05 |
| Si | 0.335 |

Here, a portion of the piezoelectric layer 2 overlapping the space 9 in plan view in the Z direction is not supported by the support 20 having a low linear expansion coefficient, and thus is easily deformed by thermal expansion of the first metal layer 11 provided at that portion of the piezoelectric layer 2.

In the example of FIG. 15, the second metal layer 12 overlaps at least a portion of the boundary 9a between the support 20 and the space 9 in plan view in the Z direction. Here, the boundary 9a between the support 20 and the space 9 refers to a cavity of the support 20 on a surface in the Z direction of the support 20 close to the piezoelectric layer 2. The cavity of the support 20 refers to the cavity 7a of the dielectric layer 7 or the cavity 8a of the support substrate 8. In other words, in FIG. 14, when a line passing through the boundary 9a and parallel to the Z direction is a line E, it can be said that the second metal layer 12 overlaps the line E.

Thus, the first metal layer 11 provided at a position overlapping the space 9 in plan view in the Z direction is also supported by the second metal layer 12. Therefore, since deformation of a portion of the piezoelectric layer 2 overlapping the space 9 in plan view in the Z direction is reduced or prevented, it is possible to further reduce or prevent an occurrence of a portion where the piezoelectric layer 2 is excessively bent.

Hereinafter, test examples will be described. In test examples of the acoustic wave device 1A according to the first example embodiment, a simulation model was created with the following design parameters.

Piezoelectric layer 2: LiNbO₃ of Euler angles (0°, 37.5°, 0°)

Thickness of piezoelectric layer 2: about 385 mm

Thickness of support substrate 8: about 50 μm

Thickness of dielectric layer 7: about 2 μm

Depth of space 9 (length in Z direction): about 1.5 μm

Thickness of first metal layer 11: about 504 nm

Thickness of second metal layer 12: about 2.9 μm

In the simulation, displacement in the Z direction of the piezoelectric layer 2 when a temperature of the piezoelectric layer 2 reached about 105° C. was calculated for acoustic wave device according to Test Examples 1 to 3. The acoustic wave device according to Test Example 1 is the acoustic wave device 1A when the first metal layer 11 and the second metal layer 12 are made of Al, and is a comparative example. The acoustic wave device according to Test Example 2 is the acoustic wave device 1A when the first metal layer 11 is made of Al and the second metal layer 12 is made of Cu, and is an example. The acoustic wave device according to Test Example 3 is the acoustic wave device 1A when the first metal layer 11 is made of Al and the second metal layer 12 is made of Au, and is an example.

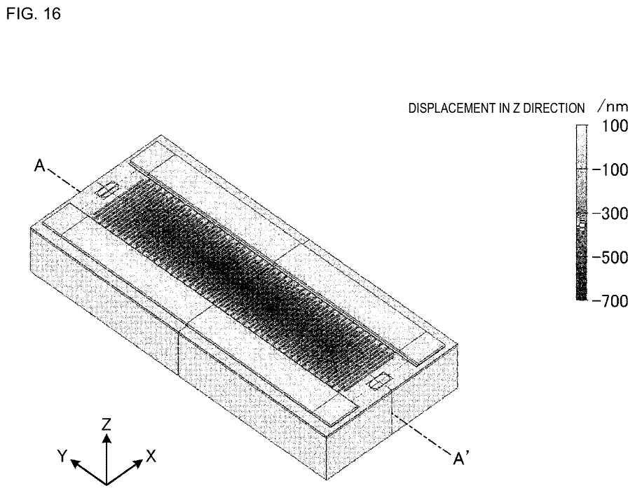

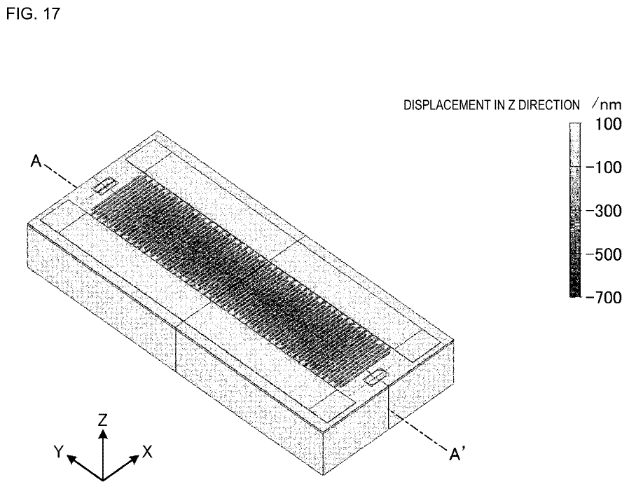

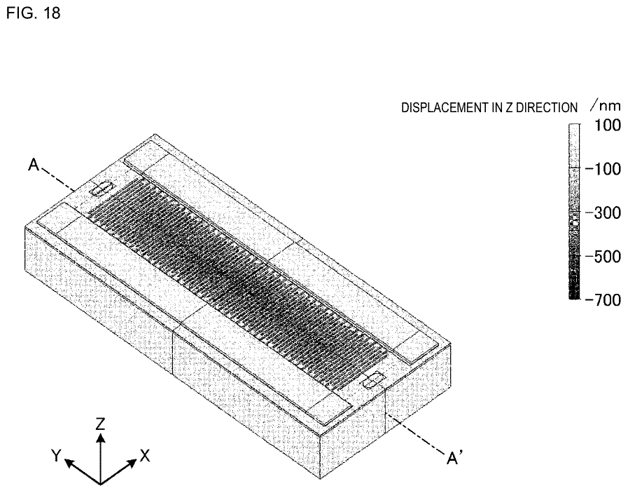

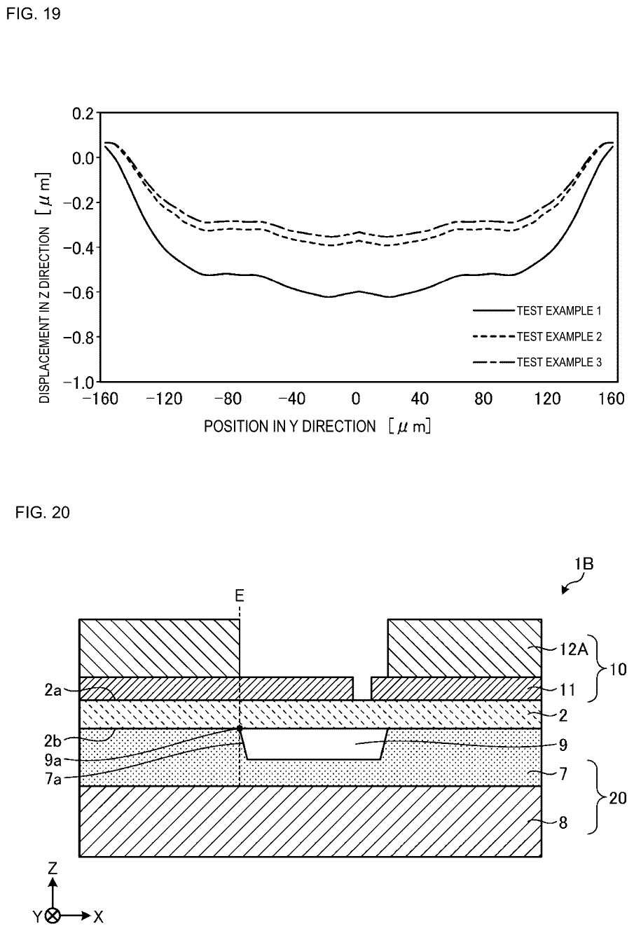

FIG. 16 is a diagram showing a distribution of the displacement in the Z direction of the piezoelectric layer of the acoustic wave device according to Test Example 1. FIG. 17 is a diagram showing a distribution of the displacement in the Z direction of the piezoelectric layer of the acoustic wave device according to Test Example 2. FIG. 18 is a diagram showing a distribution of the displacement in the Z direction of the piezoelectric layer of the acoustic wave device according to Test Example 3. FIG. 19 is a diagram showing the displacement of the piezoelectric layer in the Z direction along line A-A′ in FIG. 16 to FIG. 18. Here, in FIG. 19, a position in the Y direction refers to a distance from a center in the Y direction of the space 9.

In Test Example 1 as the comparative example, as shown in FIG. 16 and FIG. 19, the displacement of the piezoelectric layer 2 in the Z direction is large in a vicinity of the center in the Y direction of the space 9, and a portion where the piezoelectric layer 2 is excessively bent occurs.

In Test Example 2 as the example, as shown in FIG. 17 and FIG. 19, the displacement of the piezoelectric layer 2 in the Z direction is smaller than that in Test Example 1, and the bending of the piezoelectric layer 2 in the vicinity of the center in the Y direction of the space 9 is reduced or prevented. This shows that it is possible to reduce or prevent an occurrence of a portion of the piezoelectric layer 2 that is excessively bent, by setting the linear expansion coefficient of the second metal layer 12 to be smaller than the linear expansion coefficient of the first metal layer 11.

In Test Example 3 as the example, as shown in FIG. 18 and FIG. 19, the displacement of the piezoelectric layer 2 in the Z direction is further smaller than that in Test Example 1, and the bending of the piezoelectric layer 2 in the vicinity of the center in the Y direction of the space 9 is further reduced or prevented. This shows that the bending in the Z direction can be further reduced or prevented by further reducing the second metal layer 12 in size.

The acoustic wave device according to the first example embodiment is not limited to the acoustic wave device 1A illustrated in FIG. 14 and FIG. 15. Other examples will be described below with reference to the drawings. The same or similar configurations to those in FIG. 14 and FIG. 15 are denoted by the same reference numerals, and the description thereof will be omitted. In addition, in FIG. 20 to FIG. 23 described below, a line passing through the boundary 9a and parallel or substantially parallel to the Z direction may be described as the line E.

FIG. 20 is a sectional view illustrating a first modification of the acoustic wave device according to the first example embodiment. As illustrated in FIG. 20, in an acoustic wave device 1B according to the first modification, an inner end in the X direction of a second metal layer 12A overlaps a portion of the boundary 9a between the support 20 and the space 9 in plan view in the Z direction. The inner end in the X direction of the second metal layer 12A refers to an end in the X direction of the second metal layer 12 on a side where the space 9 is provided in plan view in the Z direction. In the example of FIG. 20, the inner end in the X direction of the second metal layer 12A overlaps a portion of the boundary 9a between the support 20 and the space 9, which is parallel or substantially parallel to the Y direction, in plan view in the Z direction. In other words, in FIG. 20, the inner end in the X direction of the second metal layer 12A overlaps the line E.

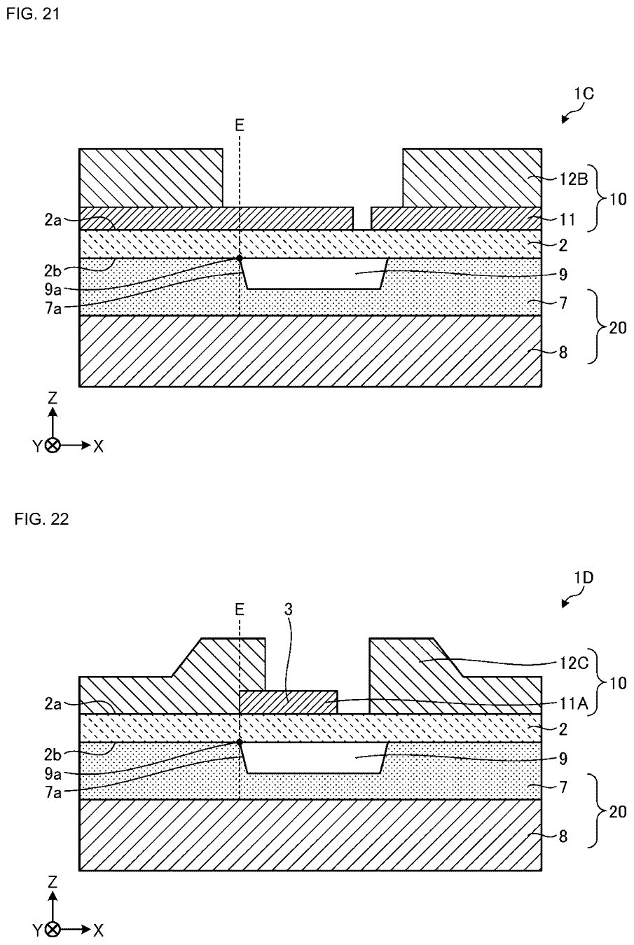

FIG. 21 is a sectional view illustrating a second modification of the acoustic wave device according to the first example embodiment. As illustrated in FIG. 21, in an acoustic wave device 1C according to the second modification, a second metal layer 12B does not overlap the boundary 9a between the support 20 and the space 9 in plan view in the Z direction. In the example of FIG. 21, the second metal layer 12B does not overlap the space 9 in plan view in the Z direction. In other words, in FIG. 21, it can be said that the second metal layer 12B does not overlap the line E.

FIG. 22 is a sectional view illustrating a third modification of the acoustic wave device according to the first example embodiment. As illustrated in FIG. 22, in an acoustic wave device 1D according to the third modification, a second metal layer 12C is laminated on a portion of a first metal layer 11A. In the example of FIG. 22, the first metal layer 11A defines the electrode fingers 3 and 4, and the second metal layer 12C defines the busbars 5 and 6, and a wiring electrode.

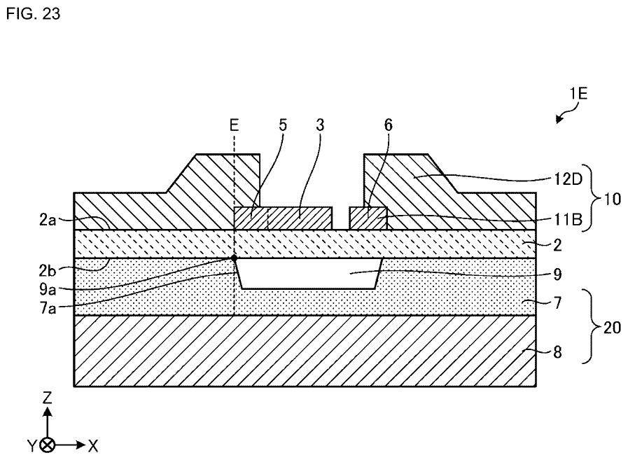

FIG. 23 is a sectional view illustrating a fourth modification of the acoustic wave device according to the first example embodiment. As illustrated in FIG. 23, in an acoustic wave device 1E according to the fourth modification, a second metal layer 12D is laminated on a portion of a first metal layer 11B. In the example of FIG. 23, the first metal layer 11B defines the electrode fingers 3 and 4, and the busbars 5 and 6, and the second metal layer 12C defines a wiring electrode.

The acoustic wave devices 1A to 1E according to the first example embodiment have been described above, but an acoustic wave device according to the first example embodiment is not limited to the acoustic wave devices 1A to 1E. For example, the support 20 need not include the dielectric layer 7, and the piezoelectric layer 2 may be provided on the support substrate 8. Further, an acoustic wave device may further include a protective film in the Z direction of the second metal layer 12.

As described above, the acoustic wave device according to the first example embodiment includes the support 20 including the support substrate 8, the piezoelectric layer 2 provided on the support 20, and the functional electrode 10 provided on the piezoelectric layer 2, wherein the support 20 includes the space 9 at a position at least partially overlapping the functional electrode 10 in plan view, the functional electrode 10 includes the first metal layer 11 and the second metal layer 12 laminated on at least a portion of the first metal layer 11, and the linear expansion coefficient of the second metal layer 12 is smaller than the linear expansion coefficient of the first metal layer 11.

Thus, the first metal layer 11 is supported by the second metal layer 12 having a linear expansion coefficient smaller than that of the first metal layer 11, and an occurrence of a portion where the piezoelectric layer 2 is excessively bent can be reduced or prevented.

The second metal layer 12 may overlap at least a portion of the boundary 9a between the support 20 and the space 9 in plan view. This makes it possible to further reduce or prevent an occurrence of a portion where the piezoelectric layer 2 is excessively bent.

A difference in linear expansion coefficient between the piezoelectric layer 2 and the second metal layer 12 may be smaller than a difference in linear expansion coefficient between the piezoelectric layer 2 and the first metal layer 11. Accordingly, the first metal layer 11 is supported by the second metal layer 12 having a linear expansion coefficient smaller than that of the first metal layer 11 having a linear expansion coefficient close to that of the piezoelectric layer 2, thus an occurrence of a portion where the piezoelectric layer 2 is excessively bent can be further reduced or prevented.

The second metal layer 12 may include Au or Cu. Thus, the linear expansion coefficient of the second metal layer 12 can be reduced.

The first metal layer 11 may include Al. Thus, good frequency characteristics can be obtained.

Further, the second metal layer 12 is the wiring electrode. In this case as well, it is possible to reduce or prevent an occurrence of a portion where the piezoelectric layer 2 is excessively bent.

Further, the support 20 may further include the dielectric layer 7 provided on the support substrate 8, and the space 9 is provided in a portion of the dielectric layer 7. In this case as well, it is possible to reduce or prevent an occurrence of a portion where the piezoelectric layer 2 is excessively bent.

The functional electrode 10 may include the first electrode fingers 3 extending in the first direction, and the second electrode fingers 4 facing corresponding ones of the first electrode fingers 3 in the second direction orthogonal or substantially orthogonal to the first direction and extending in the first direction. Thus, an acoustic wave device having good resonance characteristics can be provided.

The thickness of the piezoelectric layer 2 may be equal to or less than about 2p, where p is the center-to-center distance between the first electrode finger 3 and the second electrode finger 4 adjacent to each other among the first electrode fingers 3 and the second electrodes 4. This makes it possible to reduce the acoustic wave device 1 in size and increase the Q value.

The piezoelectric layer 2 may include lithium niobate or lithium tantalate. Thus, an acoustic wave device having good resonance characteristics can be provided.

A configuration is provided in which a bulk wave in a thickness shear mode can be utilized. This makes it possible to provide an acoustic wave device that has a high coupling coefficient and good resonance characteristics.

d/p may be equal to or less than about 0.24. This makes it possible to reduce the acoustic wave device 1 in size and increase the Q value.

A region where the first electrode finger 3 and the second electrode finger 4 overlap each other when viewed in a third direction is the excitation region C, and MR≤about 1.75(d/p)+0.075 may be satisfied where MR is a metallization ratio of the first electrode finger 3 and the second electrode finger 4 to the excitation region C. In this case, a fractional bandwidth can be reliably set to equal to or less than about 17%.

A configuration may be provided in which a plate wave can be utilized. Thus, an acoustic wave device having good resonance characteristics can be provided.

A functional electrode may include an upper electrode and a lower electrode that sandwich the piezoelectric layer 2 in the thickness direction. Thus, an acoustic wave device having good resonance characteristics can be provided.

Euler angles (φ, θ, ψ) of lithium niobate or lithium tantalate may be in a range of Expression (1), (2), or (3) below. In this case, a fractional bandwidth can be sufficiently widened.

(0°±10°, 0° to 20°, any ψ) Expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Expression (2)

(0°±10°, [180°−30° (1−(ψ−90)²/8100)^{1/2}] to 180°, any ψ) Expression (3)

Additionally, the acoustic wave device according to the first example embodiment includes the support 20 including the support substrate 8, the piezoelectric layer 2 provided on the support 20, and the functional electrodes 410 and 411 provided on the piezoelectric layer 2 and below the piezoelectric layer 2, wherein the support 20 includes the space 9 at least partially overlapping the functional electrodes 410 and 411 in plan view, the functional electrodes 410 and 411 each include the first metal layer 11 and the second metal layer 12 laminated on at least a portion of the first metal layer 11, and the linear expansion coefficient of the second metal layer 12 is smaller than the linear expansion coefficient of the first metal layer 11. Thus, the first metal layer 11 is supported by the second metal layer 12 having a linear expansion coefficient smaller than that of the first metal layer 11, and an occurrence of a portion where the piezoelectric layer 2 is excessively bent can be reduced or prevented.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a support including a support substrate;
a piezoelectric layer on the support; and
a functional electrode on the piezoelectric layer; wherein
the support includes a space at a position at least partially overlapping the functional electrode in plan view; and
the functional electrode includes a first metal layer and a second metal layer on at least a portion of the first metal layer, and a linear expansion coefficient of the second metal layer is smaller than a linear expansion coefficient of the first metal layer.

2. The acoustic wave device according to claim 1, wherein the second metal layer overlaps at least a portion of a boundary between the support and the space in plan view.

3. The acoustic wave device according to claim 1, wherein a difference in linear expansion coefficient between the piezoelectric layer and the second metal layer is smaller than a difference in linear expansion coefficient between the piezoelectric layer and the first metal layer.

4. The acoustic wave device according to claim 1, wherein the second metal layer includes Au or Cu.

5. The acoustic wave device according to claim 1, wherein the first metal layer includes Al.

6. The acoustic wave device according to claim 1, wherein the second metal layer is a wiring electrode.

7. The acoustic wave device according to claim 1, wherein
the support further includes a dielectric layer on the support substrate; and
the space is provided in a portion of the dielectric layer.

8. The acoustic wave device according to claim 1, wherein the functional electrode includes first electrode fingers extending in a first direction, and second electrode fingers facing corresponding ones of the first electrode fingers in a second direction orthogonal or substantially orthogonal to the first direction and extending in the first direction.

9. The acoustic wave device according to claim 8, wherein a thickness of the piezoelectric layer is equal to or less than about 2p, where p is a center-to-center distance between first and second electrode fingers adjacent to each other among the first electrode fingers and the second electrode fingers.

10. The acoustic wave device according to claim 8, wherein the piezoelectric layer includes lithium niobate or lithium tantalate.

11. The acoustic wave device according to claim 8, wherein the acoustic wave device is structured to generate a bulk wave in a thickness shear mode.

12. The acoustic wave device according to claim 10, wherein d/p≤about 0.5 where d is a thickness of the piezoelectric layer, and p is a center-to-center distance between first and second electrode fingers adjacent to each other among the first electrode fingers and the second electrode fingers.

13. The acoustic wave device according to claim 12, wherein d/p is equal to or less than about 0.24.

14. The acoustic wave device according to claim 8, wherein the functional electrode includes the first electrode fingers extending in the first direction and the second electrode fingers facing corresponding ones of the first electrode fingers in the second direction orthogonal or substantially orthogonal to the first direction and extending in the first direction, a region where first and second electrode fingers adjacent to each other overlap each other when viewed in a direction in which the first and second electrode fingers face each other is an excitation region, and MR≤about 1.75(d/p)+0.075 is satisfied, where MR is a metallization ratio of the first and second electrode fingers to the excitation region.

15. The acoustic wave device according to claim 1, wherein the acoustic wave device is structured to generate a plate wave.

16. The acoustic wave device according to claim 1, wherein the functional electrode includes an upper electrode and a lower electrode sandwiching the piezoelectric layer in a thickness direction.

17. The acoustic wave device according to claim 10, wherein Euler angles (φ, θ, ψ) of the lithium niobate or the lithium tantalate are in a range of Expression (1), Expression (2), or Expression (3):
(0°±10°, 0° to 20°, any ψ) Expression (1);
(0°±10°, 20° to 80°, 0° to 60° (1−(θ−50)²/900)^{1/2}) or (0°±10°, 20° to 80°, [180°−60° (1−(θ−50)²/900)^{1/2}] to) 180°) Expression (2); and
(0°±10°, [180°−30° (1−(ψ−90)²/8100)^{1/2}] to 180°, any ψ) Expression (3).

18. An acoustic wave device, comprising:
a support including a support substrate;
a piezoelectric layer on the support; and
functional electrodes on the piezoelectric layer and below the piezoelectric layer; wherein
the support includes a space at a position at least partially overlapping the functional electrodes in plan view; and
the functional electrodes each include a first metal layer and a second metal layer laminated on at least a portion of the first metal layer, and a linear expansion coefficient of the second metal layer is smaller than a linear expansion coefficient of the first metal layer.

19. The acoustic wave device according to claim 18, wherein the second metal layer overlaps at least a portion of a boundary between the support and the space in plan view.

20. The acoustic wave device according to claim 18, wherein a difference in linear expansion coefficient between the piezoelectric layer and the second metal layer is smaller than a difference in linear expansion coefficient between the piezoelectric layer and the first metal layer.
